(19) United States
(12) Patent Application Publication
(10) Pub. No.: US 2024/0421029 A1
(43) Pub. Date: Dec. 19, 2024

(54) Semiconductor Package

(71) Applicant: Wolfspeed, Inc., Durham, NC (US)

(72) Inventors: Devarajan Balaraman, Apex, NC (US); Daniel Ginn Richter, Raleigh, NC (US)

(21) Appl. No.: 18/336,358

(22) Filed: Jun. 16, 2023

(51) Int. Cl. H01L 23/373; H01L 23/00; H01L 23/31; H01L 23/498; H01L 25/07; H01L 29/66; H01L 29/872

(52) U.S. Cl. CPC H01L 23/373; H01L 23/3128; H01L 23/49827; H01L 24/16; H01L 24/32; H01L 25/072; H01L 29/66212; H01L 29/872; H01L 2224/16227; H01L 2224/32227; H01L 2224/32235; H01L 2225/06513; H01L 2924/10253; H01L 2924/18161

(57) ABSTRACT

Semiconductor packages are provided. In one example, a semiconductor package includes a submount having a first surface and a second surface opposing the first surface. The semiconductor package includes at least one semiconductor die attached to the second surface of submount. The semiconductor package includes an insulating portion on the second surface of the submount and on the at least one semiconductor die. The insulating portion forms a first external surface of the semiconductor package. The semiconductor package includes at least one through-mold via extending from the first external surface through the insulating portion to at least one of the semiconductor die or the submount.

### FIELD

The present disclosure relates generally to semiconductor packages.

### BACKGROUND

Semiconductor devices such as transistors and diodes are ubiquitous in modem electronic devices. Wide band gap semiconductor material systems such as gallium arsenide (GaAs), gallium nitride (GaN), and silicon carbide (SiC) are being increasingly utilized in semiconductor devices to push the boundaries of device performance in areas such as switching speed, power handling capability, and thermal conductivity. Example semiconductor devices may include metal-oxide-semiconductor field-effect transistors (MOSFETs), insulated gate bipolar transistors (IGBTs), Schottky barrier diodes, PiN diodes, thyristors, and high electron mobility transistors (HEMTs). Packaging technology may play a large role in the performance of semiconductor devices.

### SUMMARY

Aspects and advantages of embodiments of the present disclosure will be set forth in part in the following description, or may be learned from the description, or may be learned through practice of the embodiments.

One example embodiment of the present disclosure is directed to a semiconductor package. The semiconductor package includes a submount having a first surface and a second surface opposing the first surface. The semiconductor package includes at least one semiconductor die attached to the second surface of submount. The semiconductor package includes an insulating portion on the second surface of the submount and on the at least one semiconductor die. The insulating portion forms a first external surface of the semiconductor package. The semiconductor package includes at least one through-mold via extending from the first external surface through the insulating portion to at least one of the semiconductor die or the submount.

Another example embodiments of the present disclosure is directed to a submount having a first surface and a second surface. The second surface opposes the first surface. The semiconductor package includes at least one semiconductor die. The at least one semiconductor die includes a first die surface having a drain contact and a second die surface having a source contact and a gate contact. The drain contact is coupled to the first surface of the submount. The semiconductor package includes an insulating portion on the submount and on the semiconductor die, the insulating portion forming a first external surface of the semiconductor package. The semiconductor package includes a first through-mold via extending from the first external surface through the insulating portion to the gate contact. The semiconductor package includes a second through-mold via extending from the first external surface through the insulating portion to the drain contact. The semiconductor package includes a third through-mold via extending from the first external surface through the insulating portion to the submount. The drain contact is coupled to the third through-mold via with the submount.

Another example embodiment of the present disclosure is directed to a method of forming a semiconductor package. The method includes coupling at least one semiconductor die to a first surface of a submount. The submount has a second surface opposing the first surface. The method includes forming an insulating portion on the submount such that the insulating portion is on the at least one semiconductor die. The insulating portion forms a first external surface of the semiconductor package. The method includes forming at least one through-mold via extending from the first external surface through the insulating portion to the at least one semiconductor die or to the submount.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a cross-sectional view of a semiconductor package according to example embodiments of the present disclosure.

FIG. 2 depicts a top perspective view of a semiconductor package according to example embodiments of the present disclosure.

FIG. 3 depicts a cross-sectional view of a semiconductor package according to example embodiments of the present disclosure.

FIG. 4 depicts a cross-sectional view of a semiconductor package according to example embodiments of the present disclosure.

FIG. 5 depicts a cross-sectional view of a system including a semiconductor package mounted to a circuit board according to example embodiments of the present disclosure.

FIG. 6 depicts a flow chart diagram of a method according to example embodiments of the present disclosure.

FIG. 7 depicts a flow chart diagram of a method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor packages, such as discrete semiconductor packages and power modules, have been developed that include one or more semiconductor die. The semiconductor die may include one or more semiconductor devices, such as MOSFETs, Schottky diodes, HEMT devices. Such semiconductor packages may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, battery management systems, radio frequency applications, wireless communication infrastructure, radar, telecommunication systems (e.g., 5G communication systems), amplifiers, satellite communications, datalinks, etc.

Packaging technology for semiconductor devices may play an important role in defining the performance of the semiconductor devices. For example, the packaging of a semiconductor die may limit the ability of the semiconductor die to dissipate heat, conduct current, or even switch at particular speeds (e.g., due to stray inductance). Ineffective heat dissipation may create problems for semiconductor devices (e.g., small form factor semiconductor devices) or in situations where the semiconductor device comes into close contact with the housing. Excessive heat may adversely impact the operation of the semiconductor device itself, as well as the electronic system that uses that semiconductor device.

Certain power semiconductor packages can be predominately lead frame based. For instance, some existing semiconductor packages may include one or more wire bonds for interconnects to couple the semiconductor die to leads or other connection structures for the semiconductor package. Semiconductor packages including lead frames and wire bonds may require expensive tooling. Moreover, the semiconductor packages may suffer from parasitic effects (e.g., parasitic resistance or parasitic inductance) from the package interconnects (e.g., wire bonds).

Aspects of the present disclosure are directed to semiconductor packages based on, for instance, wafer level packaging (e.g., fan out wafer level packaging) that do not require a lead frame. The semiconductor packages, in some examples, do not require wire bonds. The semiconductor packages may provide for topside cooling, leading to enhanced thermal performance.

In some examples, a semiconductor package may include an insulating portion on the semiconductor die and forming a first external surface of the package. The semiconductor package may include a submount that acts as a second external surface of the semiconductor package. The second external surface may also provide top-side cooling for the semiconductor package. One or more semiconductor die may be attached to the submount (e.g., with a die-attach material). Connections may be made to the semiconductor die from the first external surface using through-mold vias extending from the first external surface through the insulating portion to at least one of the semiconductor die or to the submount.

In some examples, connections for the semiconductor package (e.g., solder pads, solder bumps, etc.) may all be provided on the first external surface of the package. This may allow for “flip chip” mounting of the semiconductor package to a circuit board by attaching the connections on the first external surface of the package to the circuit board. An underfill material may be provided between the first external surface of the semiconductor package and the circuit board. Underfilling the semiconductor package may eliminate creepage considerations for the semiconductor package. More particularly, creepage is a distance along an external surface (exposed to air) between two opposite polarity conductors. By underfilling the semiconductor package, there are no surfaces with opposite polarity conductors exposed to air, thus eliminating any creepage considerations for the semiconductor package.. Furthermore, in some examples, a heat dissipation element (e.g., a heat sink) may be installed contacting the first external surface.

Aspects of the present disclosure provide a number of technical effects and benefits. For instance, semiconductor packages according to examples of the present disclosure may be fabricated using a wafer level process that reduces the need for lead frames and wire bonds in the semiconductor package, resulting in reduced parasitic resistances and inductances. Lower parasitic inductance may result in faster switching speed. The semiconductor package may provide topside cooling resulting in improved system level thermal performance compared to other surface mount packages. Because the semiconductor package may be formed using a wafer level process, the semiconductor package allows for custom package form factors tailored around individual semiconductor die sizes as opposed to traditional packages that are confined to fixed size regardless of the semiconductor die that is being packaged. The customization may allow further cost savings since the bill of materials cost may be tailored to the semiconductor die size. For instance, the amount of mold compound used as an insulating portion may be tailored to the semiconductor die size.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

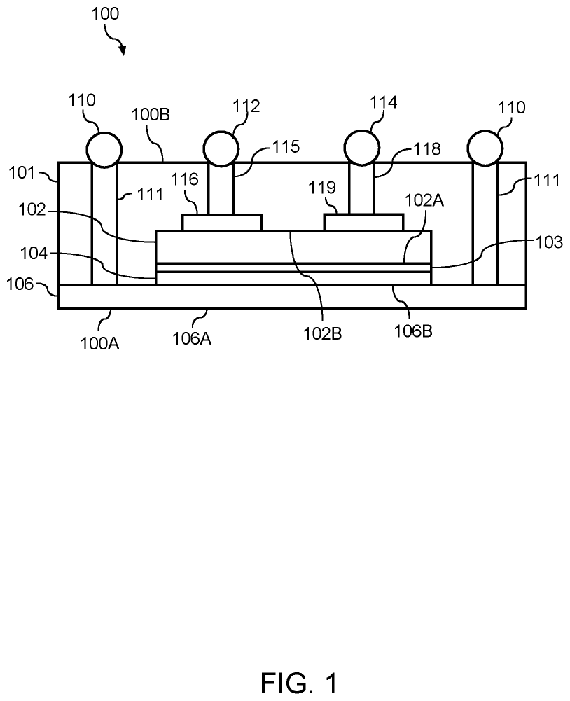

FIG. 1 depicts a cross-sectional view of a semiconductor package 100 according to example embodiments of the present disclosure. The semiconductor package 100 may include a semiconductor die 102 in thermal and/or electrical contact with a submount 106. The submount 106 may have a first surface 106A and a second surface 106B. The second surface 106B may oppose the first surface 106A. The semiconductor die 102 may be attached to the second surface 106B of the submount 106 (e.g., using a die-attach material 104). The first surface 106A of the submount 106 may be a second external surface 100A of the semiconductor package 100. The semiconductor package 100 may also define a first external surface 100B opposing the second external surface 100A.

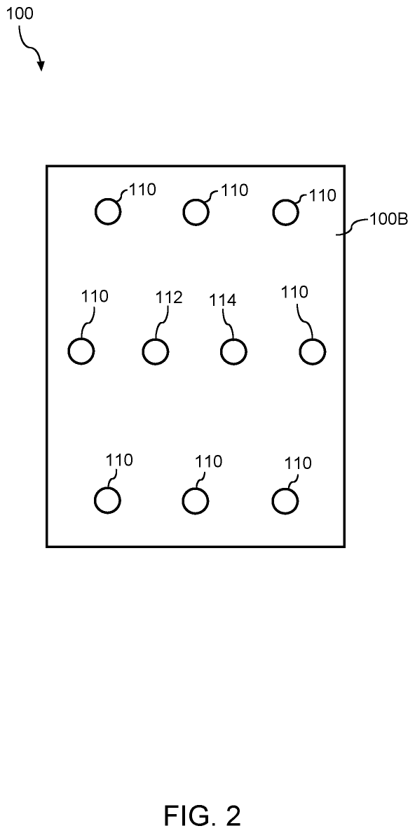

The submount 106 may be or may include a thermally and electrically conductive material. For instance, the submount 106 may form a thermally conductive cooling layer for the semiconductor package 100. As one example, the submount 106 may be or may include a metal, such as copper, silver, gold, titanium or other conductive material. In some embodiments, for example, the submount 106 may be or may include a direct bonded copper (DBC) substrate or an active metal brazed (AMB) substrate as will be discussed with reference to FIG. 2.

The semiconductor die 102 may include one or more semiconductor devices, such as MOSFET devices, Schottky diodes (e.g., silicon carbide-based Schottky diodes), Group III-nitride based high electron mobility transistors (HEMTs), or other devices. In some examples, the semiconductor die 102 may be based on or may include a wide band gap semiconductor, such as silicon carbide and/or a Group III-nitride (e.g., gallium nitride). For instance, in some examples, the semiconductor die 102 may include silicon carbide-based MOSFETs located between a source contact and a drain contact to form, for instance, a vertical structure semiconductor device. Some aspects of the present disclosure are discussed with reference to particular semiconductor devices, such as HEMT devices, silicon carbide-based MOSFET devices, silicon carbide-based Schottky diodes, etc., for purposes of illustration and discussion. Those of ordinary skill in the art, using the disclosures provided herein, will understand that the semiconductor die may include other semiconductor devices without deviating from the scope of the present disclosure, such as diodes (e.g., Schottky diodes, PiN diodes, etc.), insulated gate bipolar transistors, or other devices.

The semiconductor die 102 may be, for instance, a 7 mm by 7 mm semiconductor die. However, aspects of the present disclosure are applicable to many different semiconductor die sizes, such as 1 mm by 1 mm semiconductor die to 7 mm by 9 mm semiconductor die, as some examples. According to example aspects of the present disclosure, in some embodiments, the semiconductor package 100 does not include any wire bonds to the at least one semiconductor die 102. For instance, in some embodiments, all electrical connections to the semiconductor die 102 may be provided using through-mold vias, as described further below.

The semiconductor die 102 may include a first die surface 102A and a second die surface 102B opposing the first die surface 102A. The first die surface 102A may have a first die contact 103 (e.g., a drain contact). The second die surface 102B may have at least one second die contact. In the example of FIG. 1, the at least one second die contact includes a second die contact 116 (e.g., a gate contact) and a third die contact 119 (e.g., a source contact). It should be understood that some semiconductor die 102 may include only a single second die contact and/or greater than two second die contacts without departing from the scope of the present disclosure.

The first die contact 103 may be coupled to the submount 106. For instance, in some embodiments, the first die contact 103 may be coupled to the submount 106 with a die-attach material 104. The die-attach material 104 may be a thermally and/or electrically conductive material that is configured to attach the first die contact 103 to the submount 106. The die-attach material 104 may include any suitable material, such as, for example, solder, paste, sintered material, etc. It should be understood that, in some embodiments, the first die contact 103 may be directly connected to the submount 106 (e.g., without the use of die-attach material 104) and/or otherwise coupled to the submount 106 without departing from the scope of the present disclosure.

The semiconductor package 100 may additionally include an insulating portion 101. The insulating portion 101 may be formed on the second surface 106B of the submount 106 and on the semiconductor die 102. For instance, the insulating portion 101 may cover the semiconductor die 102 or encapsulate the semiconductor die 102. The insulating portion 101 may form the first external surface 100B of the semiconductor package 100. The insulating portion 101 may be an electrically insulating material such that the semiconductor die 102 is shielded from external electrical interference. The insulating portion 101 may be formed by a molding process. The insulating portion 101 may include a material capable of high temperature operation, such as a temperature of about 200° C. Example materials for the insulating portion 101 may include an epoxy material or an epoxy mold compound (EMC).

The semiconductor package 100 may additionally include at least one through-mold via (e.g., through-mold via 111, through-mold via 115, through-mold via 118) extending from the first external surface 100B through the insulating portion 101. For instance, the at least one through-mold via (e.g., through-mold via 111, through-mold via 115, through-mold via 118) may extend to at least one of the semiconductor die 102 or the submount 106.

More particularly, the semiconductor package 100 may include a plurality of through-mold vias 111 extending from the first external surface 100B of the semiconductor package 100 to the submount 106. The through-mold vias 111 may include an electrically conductive material (e.g., a metal) to provide an electrically conductive path to the submount 106. In addition, the through-mold vias 111 may be electrically coupled to the first die contact 103 (e.g., drain contact) through the submount 106. Although two through-mold vias 111 extending to the submount 106 are illustrated in FIG. 1, it should be understood that any suitable number of through-mold vias may couple to each contact on the semiconductor die 102 and/or the submount 106 without deviating from the present disclosure.

The semiconductor package 100 may include additional through-mold vias to provide an electrical connection(s) to the semiconductor die 102. For instance, the semiconductor package 100 may include a through-mold via 115 extending from the first external surface 100B through the insulating portion 101 to the second die contact 116 (e.g., gate contact) on the semiconductor die 102. The semiconductor package may include a through-mold via 118 extending from the first external surface 100B through the insulating portion 101 to the third die contact 119 (e.g., source contact). The semiconductor package 100 may include additional through-mold via(s) (not illustrated) to provide other electrical connections to the semiconductor die (e.g., a kelvin connection).

Each of the through-mold vias 111 may be coupled to an interconnect structure 110. The interconnect structures 110 may be configured to form electrical and/or thermal connections between the through-mold vias 111 and a surface to which the semiconductor package 100 is mounted, such as a printed circuit board (PCB). For instance, the interconnect structures 110 may be or may include a solder pad, solder bump, or other suitable interconnect structure. Furthermore, each interconnect structure 110 may be positioned on the first external surface 100B of the semiconductor package 100. In some embodiments, each interconnect structure 110 may provide a drain connection for the semiconductor package 100.

The through-mold via 115 may be coupled to an interconnect structure 112. The interconnect structure 112 may be configured to form electrical and/or thermal connections between the through-mold via 115 and a surface to which the semiconductor package 100 is mounted, such as a printed circuit board (PCB). For instance, the interconnect structure 112 may be or may include a solder pad, solder bump, or other suitable interconnect structure. Furthermore, the interconnect structure 112 may be positioned on the first external surface 100B of the semiconductor package 100. In some embodiments, the interconnect structure 112 may provide a gate connection for the semiconductor package 100.

The through-mold via 118 may be coupled to an interconnect structure 114. The interconnect structure 114 may be configured to form electrical and/or thermal connections between the through-mold via 118 and a surface to which the semiconductor package 100 is mounted, such as a printed circuit board (PCB). For instance, the interconnect structure 114 may be or may include a solder pad, solder bump, or other suitable interconnect structure. Furthermore, the interconnect structure 114 may be positioned on the first external surface 100B of the semiconductor package 100. In some embodiments, the interconnect structure 114 may provide a source connection for the semiconductor package 100. The semiconductor package 100 may include additional interconnect structures on the first external surface 110B without deviating from the scope of the present disclosure.

FIG. 2 depicts a plan view of the semiconductor package 100 (e.g., viewing the first external surface 100B) according to example embodiments of the present disclosure. The interconnect structure 112 providing, for instance, a gate connection and the interconnect structure 114 providing, for instance, a source connection are arranged on an inner portion of the external surface 100B of the semiconductor package 100. The semiconductor package 100 includes a plurality of interconnect structures 110 connected to through-mold vias 111 to provide, for instance, an electrical connection to the submount 106 and to the first die contact 103 to provide a drain connection for the semiconductor package 100. The interconnect structures 110 may at least partially surround the interconnect structure 112 and the interconnect structure 114. The plurality of interconnect structures 110 may be arranged on a peripheral portion of the external surface 100B of the semiconductor package 100 relative to the interconnect structure 112 and the interconnect structure 114.

FIG. 2 depicts one example pattern of interconnect structures 110, 112, and 114 for purposes of illustration and discussion. Those of ordinary skill in the art, using the disclosures provided herein, will understand that any pattern of interconnect structures on the external surface 100B may be used without deviating from the scope of the present disclosure.

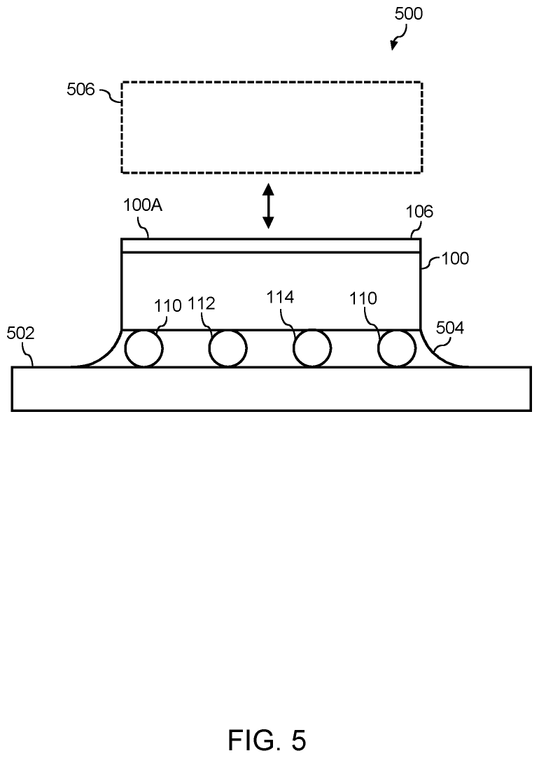

In some examples, all interconnect structures 110, 112, and 114 for the semiconductor package 100 are on the first external surface 100B to provide a flip-chip configuration for the semiconductor package 100. The semiconductor package 100 may be arranged as a surface mount technology (SMT) package with the second external surface 100A (e.g., top surface) positioned opposite an external surface, such as a printed circuit board (PCB), on which the semiconductor package 100 is mounted. The first external surface 100B (e.g., bottom surface or mounting surface) forms a mounting side of the semiconductor package 100 that is mounted to the external surface, such as a PCB. According to example aspects of the present disclosure, the second external surface 100A is defined by the submount 106 that includes a thermally conductive material (e.g., copper) such that the second external surface 100A forms a thermally-conductive cooling layer for the semiconductor package 100. Furthermore, in some implementations, the second external surface 100A may be coupled to an external heat sink to provide further topside cooling for the semiconductor package 100. A flip-chip configuration of the semiconductor package 100 will be discussed in more detail with reference to FIG. 5.

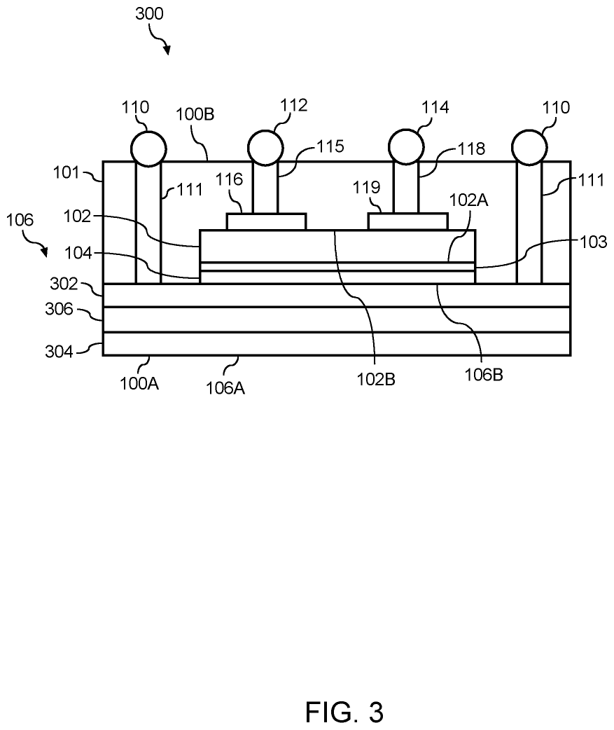

FIG. 3 depicts a cross-sectional view of a semiconductor package 300 according to example embodiments of the present disclosure. The semiconductor package 300 is similar to the semiconductor package 100 of FIG. 1. However, in the example semiconductor package 300, the submount 106 of the semiconductor package 300 includes a plurality of metal layers 302, 304, with an isolating layer 306 between the plurality of metal layers 302, 304. In some examples, the submount 106 includes a direct bonded copper (DBC) substrate or an active metal brazed (AMB) substrate.

The submount 106 may include a first metal layer 302 that is coupled to the first die contact 103 and/or the semiconductor die 102 (e.g., through die-attach material 104). The first metal layer 302 may additionally be in thermal and/or electrical contact with the through-mold vias 111. To improve electrical isolation of the first die contact 103 (e.g., the drain interconnect structure) when the semiconductor package 300 is mounted in a flip-chip configuration, the isolating layer 306 may be on the first metal layer 302. A second metal layer 304 may be on the isolating layer 306. The submount 106 may be thermally conductive, such that the submount 106 may act as a cooling pad for the semiconductor package 300. It should be understood that the example submount 106 of FIG. 3 is provided for the purposes of illustration and discussion only, and other suitable submounts 106 may be used without departing from the scope of the present disclosure.

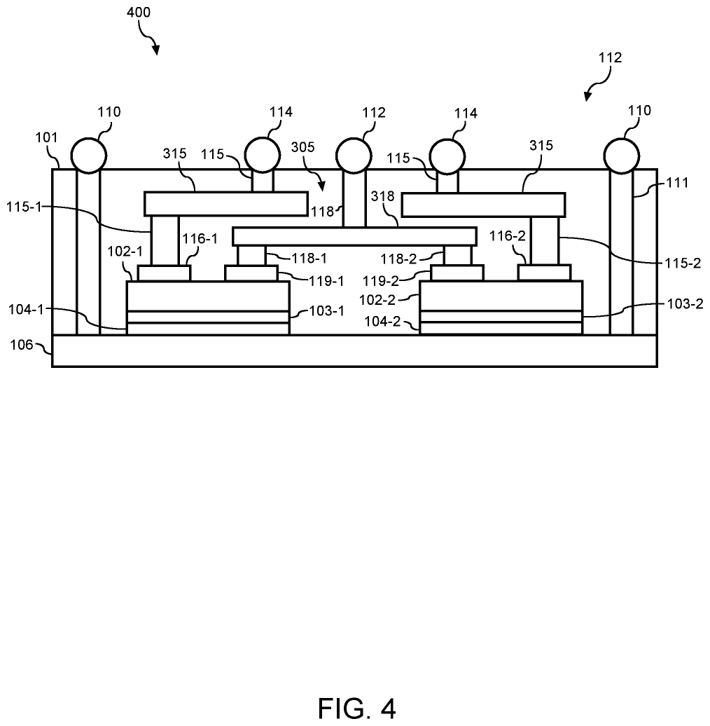

FIG. 4 depicts a cross-sectional view of a semiconductor package 400 according to example embodiments of the present disclosure. The semiconductor package 400 of FIG. 4 is similar to the semiconductor package 100. The semiconductor package 400, however, includes a plurality of semiconductor die 102-1 and 102-2. For instance, the semiconductor package 400 includes a first semiconductor die 102-1 having a first die contact 103-1 coupled to the submount 106 by a die-attach material 104-1, a second die contact 116-1, and a third die contact 119-1. Additionally, the semiconductor package 400 includes a second semiconductor die 102-2 having a first die contact 103-2 coupled to the submount 106 by a die-attach material 104-2, a second die contact 116-2, and a third die contact 119-2. Each of the semiconductor die 102-1, 102-2 may include semiconductor devices, as described above. Furthermore, more or fewer semiconductor die 102 may be included in the semiconductor package 400 without departing from the scope of the present disclosure. For instance, the semiconductor package 400 may include three or more semiconductor die 102.

The semiconductor package 400 may further include at least one redistribution layer coupling the through-mold via(s) to the plurality of semiconductor die 102-1 and 102-2. For instance, as illustrated in FIG. 4, a gate interconnect structure 112 and source interconnect structures 114 are provided that connect to the respective second die contacts 116-1, 116-2 and third die contacts 119-1, 119-2 on each semiconductor die 102-1, 102-2. The semiconductor package 400 may include a first redistribution layer 315 (e.g., a gate redistribution layer) that couples the through-mold vias 115 to the second die contacts 116-1, 116-2. For instance, the through-mold vias 115 may extend to the first redistribution layer 315. Through-mold vias 115-1, 115-2 may then extend from the first redistribution layer 315 to the second die contacts 116-1, 116-2.

Similarly, the semiconductor package 400 may include a second redistribution layer 318 (e.g., a source redistribution layer) that couples the through-mold via 118 to the third die contacts 119-1, 119-2. For instance, the through-mold via 118 may extend to the second redistribution layer 318. In some cases, holes 305 in the first redistribution layer 315 may accommodate the through-mold via 118 such that the through-mold via 118 does not contact the first redistribution layer 315. Through-mold vias 118-1, 118-2 may then extend from the second redistribution layer 318 to the third die contacts 119-1, 119-2.

The redistribution layers 315, 318 may be made of an electrically conductive material. In some embodiments, the redistribution layers 315,318 may also be thermally conductive. For instance, in some embodiments, the redistribution layers 315, 318 may be metal, such as copper, silver, gold, titanium or other conductive material. Furthermore, in some embodiments, one or more additional layers not illustrated may be included in the insulating portion 101 to improve electrical and/or thermal isolation between the redistribution layers 315, 318. In some embodiments, however, the insulating portion 101 may provide sufficient isolation between the redistribution layers 315, 318. In the case of additional contacts on the semiconductor die 102, more redistribution layers may be provided in semiconductor package 400 without departing from the scope of the present disclosure.

FIG. 5 depicts a cross-sectional view of a system 500 including a semiconductor package 100 mounted to a circuit board 502 according to example embodiments of the present disclosure. The semiconductor package 100 may be the semiconductor package 100 of FIG. 1 and/or the semiconductor packages 300, 400 of FIGS. 3 and 4, respectively. As illustrated in FIG. 5, the interconnect structures 110, 112, and 114 may all be on a single surface of the semiconductor package 100. This may allow for “flip chip” mounting of the semiconductor package 100 to the circuit board 502 by attaching the interconnect structures 110, 112, and 114 on the first external surface of the semiconductor package 100 to the circuit board 502. The semiconductor package 100 may thus be arranged as a surface mount technology (SMT) or “flip-chip” package. The second external surface 100A formed by the submount 106 of the semiconductor package 100 may thereby form a thermally-conductive cooling layer for the semiconductor package 100. Furthermore, in some implementations, the second external surface 100A formed by the submount 106 of the semiconductor package 100 opposite the circuit board 502 may be coupled to an external heat sink 506 to provide further topside cooling for the semiconductor package 100.

An underfill material 504 may be provided between the first external surface of the semiconductor package 100 and, for instance, a circuit board or other substrate. The underfill material 504 may reduce strain on the semiconductor package 100 (e.g., strain on the interconnect structures 110, 112, and 114) associated with physical forces acting on the semiconductor package, such as gravity, physical contact, inertial forces, etc. Additionally or alternatively, the underfill material 504 may eliminate the need for creepage considerations for the semiconductor package 100. For instance, the interconnect structures 110, 112, and 114 may be placed in closer proximity to one another without additional strain. The underfill material 504 may provide isolation between the interconnect structures 110, 112, and 114.

The underfill material 504 may be any suitable material. In some embodiments, the underfill material 504 may be, for instance, a composite material made up of a polymer (e.g., epoxy polymer) with filler and/or additional components. For instance, the underfill material 504 may be a polymer-based material, such as an epoxy polymer material. Additionally or alternatively, the underfill material 504 may include a filler or other components, such as a flowing agent, adhesive agent, etc.

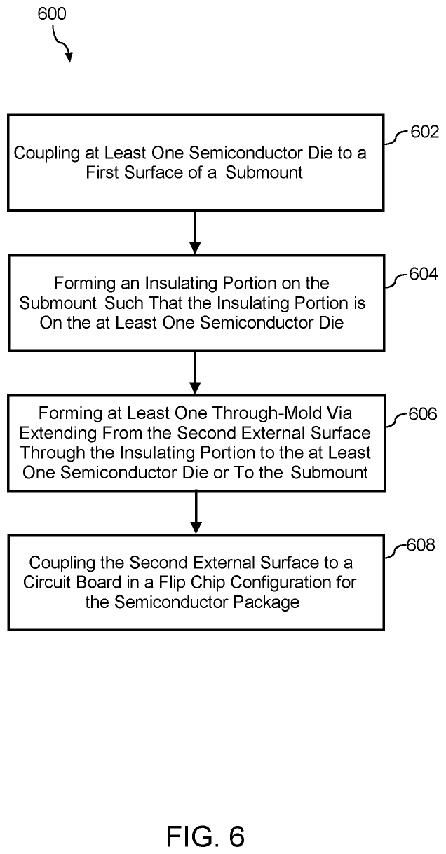

FIG. 6 depicts a flow diagram of an example method 600 of forming a semiconductor package according to example embodiments of the present disclosure. FIG. 6 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 602, the method 600 may include coupling at least one semiconductor die to a first surface of a submount. The submount may have a second surface opposing the first surface. Furthermore, the second surface may be a first external surface of the semiconductor package. Example submounts 106 and example semiconductor die 102 are discussed herein with respect to FIGS. 1-4. Notably, in some embodiments, the semiconductor package does not include any wire bonds to the at least one semiconductor die.

In some embodiments, the at least one semiconductor die may include a first die surface and a second die surface opposing the first die surface. The first die surface may have a first die contact and/or the second die surface may have a second die contact. Furthermore, in some embodiments, coupling the at least one semiconductor die to a first surface of the submount may include coupling the first die contact to the submount. For instance, in some embodiments, coupling the first die contact to the submount comprises coupling the first die contact to the submount with a die-attach material.

At 604, the method 600 may include forming an insulating portion on the submount such that the insulating portion is on the at least one semiconductor die. The insulating portion may form a first external surface of the semiconductor package. The first external surface may oppose the first external surface. The insulating portion may be formed in any suitable manner. For instance, in some embodiments, the insulating portion may be molded, such as by a fan out wafer level process. The insulating portion may cover the at least one semiconductor die. The insulating portion may include any suitable electrically and/or thermally insulating material. For instance, in some embodiments, the insulating portion may be or may include an epoxy mold compound.

At 606, the method 600 may include forming at least one through-mold via extending from the first external surface through the insulating portion to the at least one semiconductor die or to the submount. For instance, in some embodiments, forming the at least one through-mold via may include coupling the at least one through-mold via to the second die contact. As one example, a cavity for receiving the through-mold via(s) may be formed in the insulation portion, such as by drilling, molding, additive manufacturing around the cavity, or otherwise. The cavity may be filled with a conductive material to form the through-mold via. As another example, the via(s) may be formed prior to molding the insulation portion.

Furthermore, in some embodiments, the method 600 may further include forming an interconnect structure on the first external surface of the semiconductor package. The interconnect structure may be electrically coupled to the at least one through-mold via. For instance, one or more solder bumps, solder pads, etc. may be formed that are electrically coupled to the through-mold vias. The interconnect structures may facilitate coupling the semiconductor package to a circuit board.

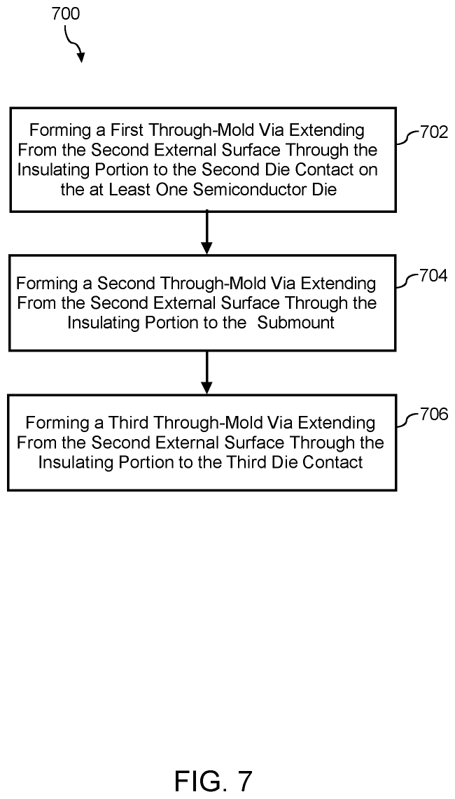

In some embodiments, forming the at least one through-mold via may include forming a plurality of through-mold vias. For instance, FIG. 7 illustrates a method for forming a plurality of through-mold vias according to example embodiments of the present disclosure. FIG. 7 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 702, the method 700 may include forming a first through-mold via extending from the first external surface through the insulating portion to the second die contact on the at least one semiconductor die. For instance, the first through-mold via may be a source via forming a source interconnect structure to a source contact of the semiconductor die.

At 704, the method 700 may include forming a second through-mold via extending from the first external surface through the insulating portion to the submount. The second through-mold via may be electrically coupled to the first die contact through the submount. For instance, in some embodiments, the second through-mold via may be a drain via forming a drain interconnect structure to a drain contact of the semiconductor die.

Furthermore, in some embodiments, such as embodiments where the at least one semiconductor die includes a third die contact on the second die surface, the method 700 may include forming a third through-mold via extending from the first external surface through the insulating portion to the third die contact. For instance, in some embodiments, the third through-mold via may be a gate via forming a gate interconnect structure to a gate contact on the semiconductor die.

Returning now to FIG. 6, the method 600 may further include, at 608, coupling the first external surface to a circuit board in a flip chip configuration for the semiconductor package. For instance, the semiconductor package may be bump bonded, soldered, or otherwise coupled such that the first external surface acts as a cooling pad for the semiconductor package. Furthermore, in some embodiments, the method 600 may further include providing an underfill material between the first external surface and the circuit board.

In some embodiments, the method 600 may be implemented as a fan out wafer level process. In fan out wafer level processes, a wafer is first diced into one or more semiconductor die. The semiconductor die may then be precisely repositioned on a carrier wafer or panel. Space for fan out may be maintained around the perimeter of the die. The insulating portion may then be formed by reconstituting the carrier, such as by molding. A submount or redistribution layer may then be formed atop the molded area (e.g., both atop the semiconductor die and the adjacent fan-out area). The vias may be formed in the insulation portion after the submount is formed. Finally, the interconnect structures may then be formed on top of the vias. It should be understood that the steps of the method 600 may be performed in any order, such as in the fan out wafer level process flow described above.

Example aspects of the present disclosure are set forth below. Any of the below features or examples may be used in combination with any of the embodiments or features provided in the present disclosure.

One example embodiment of the present disclosure is directed to a semiconductor package. The semiconductor package includes a submount having a first surface and a second surface opposing the first surface. The semiconductor package includes at least one semiconductor die attached to the second surface of submount. The semiconductor package includes an insulating portion on the second surface of the submount and on the at least one semiconductor die. The insulating portion forms a first external surface of the semiconductor package. The semiconductor package includes at least one through-mold via extending from the first external surface through the insulating portion to at least one of the semiconductor die or the submount.

In some examples, the first surface of the submount is a second external surface of the semiconductor package. The second external surface opposes the first external surface.

In some examples, the at least one through-mold via comprises a plurality of through-mold vias. The semiconductor package includes a plurality of interconnect structures. Each interconnect structure is coupled to at least one of the plurality of through-mold vias. Each interconnect structure is on the first external surface of the semiconductor package.

In some examples, all interconnect structures for the semiconductor package are on the first external surface to provide a flip-chip configuration for the semiconductor package.

In some examples, each interconnect structure comprises a solder pad or a solder bump.

In some examples, the at least one semiconductor die includes a first die surface and a second die surface opposing the first die surface. The first die surface has a first die contact and the second die surface has a second die contact. In some examples, the first die contact is coupled to the submount. In some examples, the first die contact is coupled to the submount with a die-attach material. In some examples, the at least one through-mold via is coupled to the second die contact.

In some examples, the at least one through-mold via includes: a first through-mold via extending from the first external surface through the insulating portion to the second die contact on the at least one semiconductor die; and a second through-mold via extending from the first external surface through the insulating portion to the submount. The second through-mold via is electrically coupled to the first die contact through the submount.

In some examples, the at least one semiconductor die comprises a third die contact on the second die surface. In some examples, the at least one through-mold via includes a third through-mold via extending from the first external surface through the insulating portion to the third die contact.

In some examples, the semiconductor package includes a plurality of second through-mold vias extending from the first external surface through the insulating portion to the submount.

In some examples, the submount includes a thermally and electrically conductive material. In some examples, the submount includes a metal. In some examples, the submount includes a plurality of metal layers with an isolating layer between the plurality of metal layers. In some examples, the submount comprises a direct bonded copper (DBC) substrate or an active metal brazed (AMB) substrate. In some examples, the submount forms a thermally conductive cooling layer for the semiconductor package.

In some examples, the semiconductor package includes a plurality of semiconductor die. The semiconductor package further includes a redistribution layer coupling the at least one through-mold via to the plurality of semiconductor die.

In some examples, the semiconductor package does not include any wire bonds to the at least one semiconductor die.

In some examples, the insulating portion covers the at least one semiconductor die.

In some examples, the insulating portion comprises an epoxy mold compound.

In some examples, the at least one semiconductor die comprises a wide band gap semiconductor. In some examples, the wide band gap semiconductor is silicon carbide or a Group Ill-nitride.

In some examples, the at least one semiconductor die comprises a silicon carbide-based MOSFET. In some examples, the at least one semiconductor die comprises a silicon carbide-based Schottky diode. In some examples, the at least one semiconductor die comprises a Group III-nitride based high electron mobility transistor.

Another example embodiments of the present disclosure is directed to a submount having a first surface and a second surface. The second surface opposes the first surface. The semiconductor package includes at least one semiconductor die. The at least one semiconductor die includes a first die surface having a drain contact and a second die surface having a source contact and a gate contact. The drain contact is coupled to the first surface of the submount. The semiconductor package includes an insulating portion on the submount and on the semiconductor die, the insulating portion forming a first external surface of the semiconductor package. The semiconductor package includes a first through-mold via extending from the first external surface through the insulating portion to the gate contact. The semiconductor package includes a second through-mold via extending from the first external surface through the insulating portion to the drain contact. The semiconductor package includes a third through-mold via extending from the first external surface through the insulating portion to the submount. The drain contact is coupled to the third through-mold via with the submount.

In some examples, the first surface of the submount is a second external surface of the semiconductor package. The second external surface opposes the first external surface.

In some examples, the semiconductor package includes a gate interconnect structure, a source interconnect structure, and a drain interconnect structure on the first external surface.

In some examples, the gate interconnect structure is coupled to the first through-mold via, the source interconnect structure is coupled to the second through-mold via, and the drain interconnect structure is coupled to the third through-mold via.

In some examples, the gate interconnect structure, the source interconnect structure, and the drain interconnect structure each comprise one or more solder pads or one or more solder bumps.

In some examples, the first external surface of the semiconductor package is mounted to a printed circuit board in a flip chip configuration. In some examples, the package includes an underfill material between the semiconductor package and the printed circuit board.

In some examples, the submount includes a thermally and electrically conductive material. In some examples, the submount includes a metal. In some examples, the submount includes a plurality of metal layers with an isolating layer between the plurality of metal layers. In some examples, the submount comprises a direct bonded copper (DBC) substrate or an active metal brazed (AMB) substrate. In some examples, the submount forms a thermally conductive cooling layer for the semiconductor package.

In some examples, the semiconductor package does not include any wire bonds to the at least one semiconductor die.

In some examples, the insulating portion covers the at least one semiconductor die.

In some examples, the insulating portion comprises an epoxy mold compound.

In some examples, the at least one semiconductor die comprises a wide band gap semiconductor. In some examples, the wide band gap semiconductor is silicon carbide or a Group Ill-nitride.

In some examples, the at least one semiconductor die comprises a silicon carbide-based MOSFET. In some examples, the at least one semiconductor die comprises a silicon carbide-based Schottky diode. In some examples, the at least one semiconductor die comprises a Group Ill-nitride based high electron mobility transistor.

Another example embodiment of the present disclosure is directed to a method of forming a semiconductor package. The method includes coupling at least one semiconductor die to a first surface of a submount. The submount has a second surface opposing the first surface. The method includes forming an insulating portion on the submount such that the insulating portion is on the at least one semiconductor die. The insulating portion forms a first external surface of the semiconductor package. The method includes forming at least one through-mold via extending from the first external surface through the insulating portion to the at least one semiconductor die or to the submount.

In some examples, the first surface of the submount is a second external surface of the semiconductor package. The second external surface opposes the first external surface.

In some examples, the method is a fan out wafer level process.

In some examples, the at least one semiconductor die includes a first die surface and a second die surface opposing the first die surface. The first die surface has a first die contact and the second die surface has a second die contact. Coupling the at least one semiconductor die to a first surface of the submount comprises coupling the first die contact to the submount.

In some examples, the method includes forming the at least one through-mold via comprises coupling the at least one through-mold via to the second die contact.

In some examples, forming the at least one through-mold via includes: forming a first through-mold via extending from the first external surface through the insulating portion to the second die contact on the at least one semiconductor die; and forming a second through-mold via extending from the first external surface through the insulating portion to the submount. The second through-mold via is electrically coupled to the first die contact through the submount.

In some examples, the at least one semiconductor die comprises a third die contact on the second die surface. In some examples, forming the at least one through-mold via includes forming a third through-mold via extending from the first external surface through the insulating portion to the third die contact.

In some examples, the submount includes a thermally and electrically conductive material. In some examples, the submount includes a metal. In some examples, the submount includes a plurality of metal layers with an isolating layer between the plurality of metal layers. In some examples, the submount comprises a direct bonded copper (DBC) substrate or an active metal brazed (AMB) substrate. In some examples, the submount forms a thermally conductive cooling layer for the semiconductor package.

In some examples, the method includes forming an interconnect structure on the first external surface of the semiconductor package. The interconnect structure is electrically coupled to the at least one through-mold via. In some examples, the interconnect structure includes a solder pad or a solder bump.

In some examples, the method includes coupling the first external surface to a circuit board in a flip chip configuration for the semiconductor package. In some examples, the method includes providing an underfill material between the first external surface and the circuit board.

In some examples, the semiconductor package does not include any wire bonds to the at least one semiconductor die.

In some examples, the insulating portion covers the at least one semiconductor die.

In some examples, the insulating portion comprises an epoxy mold compound.

In some examples, the at least one semiconductor die comprises a wide band gap semiconductor. In some examples, the wide band gap semiconductor is silicon carbide or a Group III-nitride.

In some examples, the at least one semiconductor die comprises a silicon carbide-based MOSFET. In some examples, the at least one semiconductor die comprises a silicon carbide-based Schottky diode. In some examples, the at least one semiconductor die comprises a Group III-nitride based high electron mobility transistor.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor package, comprising:
a submount having a first surface and a second surface opposing the first surface;
at least one semiconductor die attached to the second surface of submount;
an insulating portion on the second surface of the submount and on the at least one semiconductor die, the insulating portion forming a first external surface of the semiconductor package; and
at least one through-mold via extending from the first external surface through the insulating portion to at least one of the semiconductor die or the submount.

2. The semiconductor package of claim 1, wherein the first surface of the submount is a second external surface of the semiconductor package, the second external surface opposing the first external surface.

3. The semiconductor package of claim 2, wherein the at least one through-mold via comprises a plurality of through-mold vias, wherein the semiconductor package further comprises a plurality of interconnect structures, each interconnect structure coupled to at least one of the plurality of through-mold vias, each interconnect structure on the first external surface of the semiconductor package.

4. The semiconductor package of claim 3, wherein all interconnect structures for the semiconductor package are on the first external surface to provide a flip-chip configuration for the semiconductor package.

5. The semiconductor package of claim 3, wherein each interconnect structure comprises a solder pad or a solder bump.

6. The semiconductor package of claim 1, wherein the at least one semiconductor die comprises a first die surface and a second die surface opposing the first die surface, the first die surface having a first die contact and the second die surface having a second die contact.

7. The semiconductor package of claim 6, wherein the first die contact is coupled to the submount.

8. (canceled)

9. The semiconductor package of claim 6, wherein the at least one through-mold via is coupled to the second die contact.

10. The semiconductor package of claim 6, wherein the at least one through-mold via comprises:
a first through-mold via extending from the first external surface through the insulating portion to the second die contact on the at least one semiconductor die; and
a second through-mold via extending from the first external surface through the insulating portion to the submount, the second through-mold via electrically coupled to the first die contact through the submount.

11. The semiconductor package of claim 10, wherein the at least one semiconductor die comprises a third die contact on the second die;
wherein the at least one through-mold via comprises: a third through-mold via extending from the first external surface through the insulating portion to the third die contact.

12.-15. (canceled)

16. The semiconductor package of claim 1, wherein the submount comprises a plurality of metal layers with an isolating layer between the plurality of metal layers.

17. (canceled)

18. The semiconductor package of claim 1, wherein the submount forms a thermally conductive cooling layer for the semiconductor package.

19. The semiconductor package of claim 1, wherein the semiconductor package comprises a plurality of semiconductor die, wherein the semiconductor package further comprises a redistribution layer coupling the at least one through-mold via to the plurality of semiconductor die.

20. The semiconductor package of claim 1, wherein the semiconductor package does not include any wire bonds to the at least one semiconductor die.

21. The semiconductor package of claim 1, wherein the insulating portion covers the at least one semiconductor die.

22. The semiconductor package of claim 1, wherein the insulating portion comprises an epoxy mold compound.

23. The semiconductor package of claim 1, wherein the at least one semiconductor die comprises a wide band gap semiconductor, wherein the wide band gap semiconductor is silicon carbide or a Group III-nitride.

24. (canceled)

25. The semiconductor package of claim 1, wherein the at least one semiconductor die comprises a silicon carbide-based MOSFET, a silicon carbide-based Schottky diode, or a Group III-nitride based high electron mobility transistor.

26.-27. (canceled)

28. A semiconductor package, comprising:
a submount having a first surface and a second surface, the second surface opposing the first surface;
at least one semiconductor die, the at least one semiconductor die comprising a first die surface having a drain contact and a second die surface having a source contact and a gate contact, the drain contact being coupled to the first surface of the submount;
an insulating portion on the submount and on the semiconductor die, the insulating portion forming a first external surface of the semiconductor package;
a first through-mold via extending from the first external surface through the insulating portion to the gate contact;
a second through-mold via extending from the first external surface through the insulating portion to the drain contact; and
a third through-mold via extending from the first external surface through the insulating portion to the submount, wherein the drain contact is coupled to the third through-mold via with the submount.

29.-46. (canceled)

47. A method of forming a semiconductor package, the method comprising:
coupling at least one semiconductor die to a first surface of a submount, the submount having a second surface opposing the first surface;
forming an insulating portion on the submount such that the insulating portion is on the at least one semiconductor die, the insulating portion forming a first external surface of the semiconductor package; and
forming at least one through-mold via extending from the first external surface through the insulating portion to the at least one semiconductor die or to the submount.

48.-71. (canceled)
